(19) United States
(12) Patent Application Publication
(10) Pub. No.: US 2020/0341058 A1
(43) Pub. Date: Oct. 29, 2020

(54) Time-limited debug mode

(71) Applicant: NUVOTON TECHNOLOGY CORPORATION, Hsin-chu (TW)

(72) Inventor: Yuval Kirschner, Even Yehuda (IL)

(21) Appl. No.: 16/396,706

(22) Filed: Apr. 28, 2019

(51) Int. Cl. G01R 31/317

(52) U.S. Cl. CPC G01R 31/31705; G01R 31/31721

(57) ABSTRACT

Embodiments of the present invention include an apparatus including a debug interface, a counter, and debug-enabling circuitry. The debug-enabling circuitry is configured to receive a debug-enabling input, and responsively to the debug-enabling input, enable the debug interface and start the counter. The counter is configured to output an output signal that causes the debug interface to become disabled, following a predetermined duration from a time at which the counter was started. Other embodiments are also described.

### FIELD OF THE INVENTION

The present invention relates to digital circuitry, such as integrated circuits.

### BACKGROUND

Some integrated circuits (ICs) are configured to operate in a debug mode, whereby, via a debug interface, a user may override the regular functionality of the IC. Such a mode may be useful for product quality assurance (PQA), which may be performed, for example, in accordance with the Joint Test Action Group (JTAG) standard.

### SUMMARY OF THE INVENTION

There is provided, in accordance with some embodiments of the present invention, an apparatus including a debug interface, a counter, and debug-enabling circuitry. The debug-enabling circuitry is configured to receive a debug-enabling input, and responsively to the debug-enabling input, enable the debug interface and start the counter. The counter is configured to output an output signal that causes the debug interface to become disabled, following a predetermined duration from a time at which the counter was started.

In some embodiments, the counter is configured to output the output signal to the debug interface.

In some embodiments, the counter is configured to output the output signal to the debug-enabling circuitry, and the debug-enabling circuitry is configured to disable the debug interface in response to the output signal.

In some embodiments, the apparatus further includes resetting circuitry, the counter is configured to output the output signal to the resetting circuitry, and the resetting circuitry is configured to revert, in response to the output signal, any changes made via the debug interface while the debug interface was enabled.

In some embodiments, the resetting circuitry includes power-on reset (PoR) circuitry configured to interpret the output signal as an indication of a power-on event.

In some embodiments, the apparatus further includes:

one or more resettable components; and

one or more non-resettable components,

an element selected from the group of elements consisting of: the counter, and the debug-enabling circuitry is configured to inhibit the non-resettable components from being changed via the debug interface while the debug interface is enabled, and

the resetting circuitry is configured to revert the changes by resetting the resettable components.

In some embodiments, the resettable components include a volatile memory, and the non-resettable components include a non-volatile memory.

In some embodiments, the debug-enabling circuitry is further configured to:

receive another debug-enabling input, prior to the predetermined duration from the time at which the counter was started, and

responsively to the other debug-enabling input, restart the counter.

In some embodiments, the debug-enabling circuitry is configured not to restart the counter prior to the predetermined duration from the time at which the counter was started, even in response to receiving another debug-enabling input.

In some embodiments, the counter is further configured not to restart prior to the predetermined duration, even in response to receiving a restart instruction.

There is further provided, in accordance with some embodiments of the present invention, a method including receiving, by debug-enabling circuitry belonging to a digital circuit, a debug-enabling input. The method further includes, using the debug-enabling circuitry, responsively to the debug-enabling input, enabling a debug interface belonging to the digital circuit and starting a counter. The method further includes, following a predetermined duration from a time at which the counter was started, causing the debug interface to become disabled by outputting an output signal from the counter.

The present invention will be more fully understood from the following detailed description of embodiments thereof, taken together with the drawings, in which:

### BRIEF DESCRIPTION OF THE DRAWINGS

FIG. 1 is a schematic illustration of an integrated circuit, in accordance with some embodiments of the present invention; and

FIG. 2 is a state diagram for the integrated circuit shown in FIG. 1, in accordance with some embodiments of the present invention.

### DETAILED DESCRIPTION OF EMBODIMENTS

### Overview

Often, following the manufacturing of an IC or of a system that includes an IC, the manufacturer of the IC or of the system locks (or “disables”) the debug interface of the IC. Subsequently, to unlock (or “enable”) the debug interface and hence enable the debug mode of the IC, the user must input a particular debug-enabling input over a particular input interface belonging to the IC. For example, the user may be required to input a particular stream of bits or a particular sequence of voltages over one or more particular pins or balls belonging to the IC.

The debug-enabling input is typically kept secret by the manufacturer, so as to prevent unauthorized modifications to the functionality of the IC. (Often, the input interface over which the debug-enabling input must be entered is also kept secret.) In some cases, however, a hacker may steal this secret information. Using the stolen secret, the hacker may enable the debug interface, and then, via the debug interface, use the IC or the system in a manner that was not intended by the manufacturer.

To address this challenge, embodiments of the present invention configure the IC to remain in the debug mode for a predefined duration. This duration is large enough to allow legitimate ad hoc use of the IC, such as for PQA purposes, yet is small enough to inhibit most illegitimate uses.

More specifically, in embodiments of the present invention, the IC comprises a counter, which is connected to debug-enabling circuitry. In response to receiving the secret debug-enabling input, the debug-enabling circuitry enables the debug interface and also starts the counter. Subsequently, after the predefined duration, the counter outputs an output signal to the debug-enabling circuitry. In response to the output signal, the debug-enabling circuitry disables the debug interface.

In some embodiments, the IC further comprises resetting circuitry, which is also connected to the counter. In response to the output signal from the counter, the resetting circuitry resets the IC, thus reverting any changes that were made while the IC was in the debug mode so as to restore the normal functionality of the IC.

Typically, in addition to limiting the amount of time for which the debug mode is enabled, embodiments of the present invention limit the number and/or type of components that may be accessed by the user via the debug interface. For example, the user may be allowed to access some registers or random-access memory (RAM) components, whose contents are erased upon the resetting of the IC, but may be inhibited from accessing the counter or any non-volatile memory components.

In some embodiments, the counter cannot be restarted while debugging is enabled, such that the debug mode is always in effect for the same, predetermined duration. In other embodiments, reentering the debug-enabling input restarts the counter, such that the debug mode can be extended indefinitely by repeatedly entering the debug-enabling input. Even such embodiments, however, may inhibit hackers from exploiting the IC, given that repeatedly entering the debug-enabling input would typically require dedicated hardware that is not native to the system.

### Apparatus Description

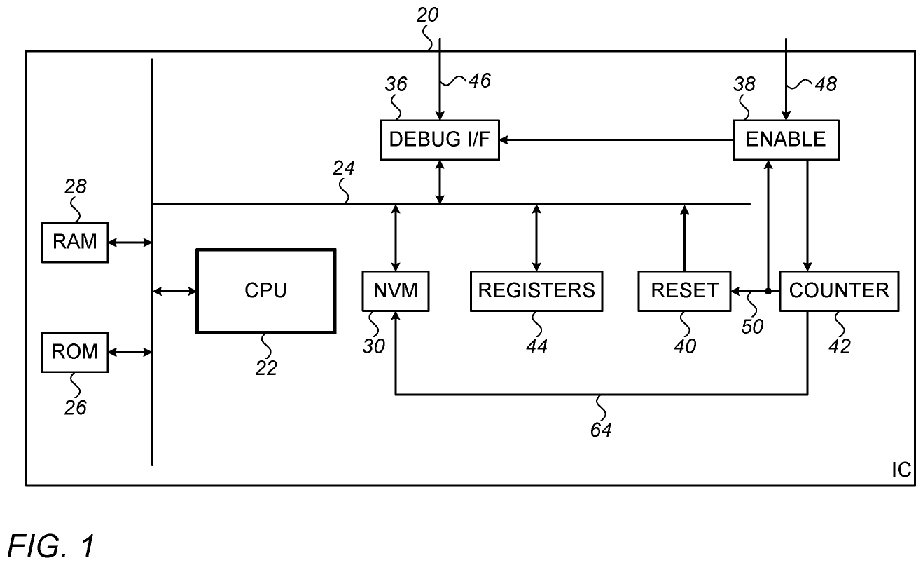

Reference is initially made to FIG. 1, which is a schematic illustration of an integrated circuit (IC) 20, in accordance with some embodiments of the present invention. IC 20 may be installed in an electronic device, such as a consumer electronics device, or in any other suitable system.

IC 20 comprises a debug interface (I/F) 36, which is configured to receive, when enabled, debugging input 46, e.g., in accordance with the JTAG standard. Debugging input 46 may cause changes to the functionality of IC 20.

As described above in the Overview, to enable debug interface 36, the user must input a particular debug-enabling input 48, including, for example, a particular stream of bits or a particular sequence of voltages, over a particular input interface. IC 20 thus further comprises debug-enabling circuitry 38, which is connected to the particular input interface. Debug-enabling circuitry 38 is configured to receive debug-enabling input 48 and, responsively to debug-enabling input 48, enable debug interface 36. (If an incorrect input is entered, the debug-enabling circuitry does not enable the debug interface.) For example, responsively to the debug-enabling input, debug-enabling circuitry 38 may change the functionality of particular pins or balls belonging to the IC, such that debugging input 46 entered over these pins or balls may be received by debug interface 36.

Also in response to debug-enabling input 48, the debug-enabling circuitry starts a counter 42. Counter 42 is configured to output an output signal 50, which causes debug interface 36 to become disabled, following a predetermined duration from the time at which the counter was started. (In other words, the counter outputs output signal 50 after counting down the predetermined duration.) For example, following the predetermined duration, the counter may generate an internal terminal count (TC) signal, which may in turn generate output signal 50. The predetermined duration may have any suitable value.

In some embodiments, the counter directly disables the debug interface by outputting the output signal to the debug interface. In other embodiments, as shown in FIG. 1, the counter outputs the output signal to the debug-enabling circuitry, and the debug-enabling circuitry disables the debug interface in response to the output signal.

In some embodiments, the counter outputs the output signal to resetting circuitry 40. In response to output signal 50, resetting circuitry 40 resets the IC, thus reverting any changes that were made to the IC via the debug interface while the debug interface was enabled. For example, the resetting circuitry may reset one or more resettable components belonging to the IC, thus restoring the normal functionality of the IC.

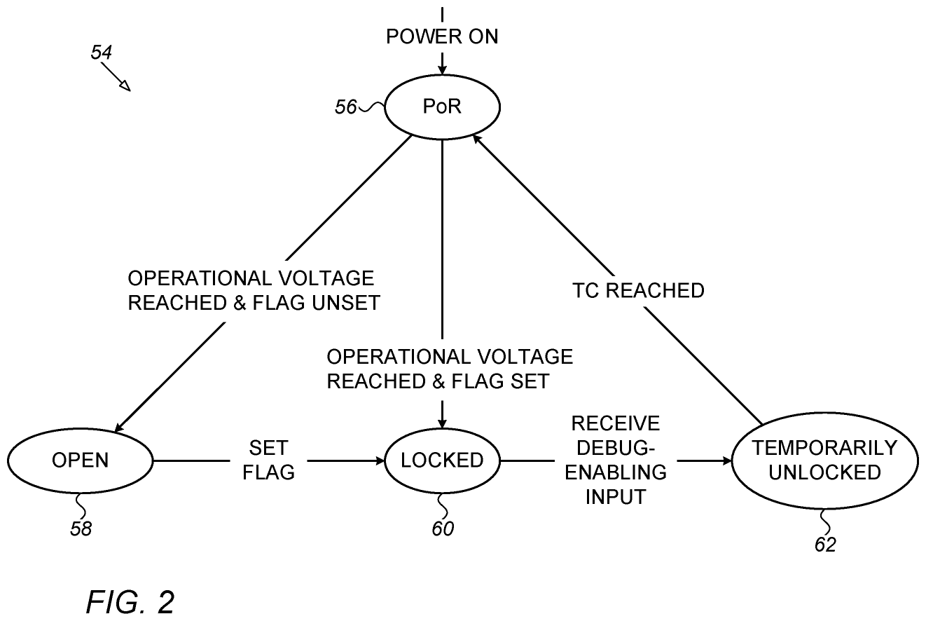

In some embodiments, as assumed below in the description of FIG. 2, resetting circuitry 40 comprises power-on reset (PoR) circuitry, configured to interpret output signal 50 as an indication of a power-on event. In such embodiments, rather than providing dedicated resetting circuitry for handling output signal 50, conventional PoR circuitry may be modified so as to respond to the output signal (by resetting the IC) as if the output signal were an indication of a power-on event.

In some embodiments, the counter outputs the output signal to resetting circuitry 40 in addition to debug interface 36 or debug-enabling circuitry 38. In other embodiments, the counter does not output the output signal to debug interface 36 or to debug-enabling circuitry 38; rather, debug interface 36 is disabled as part of the resetting action performed by resetting circuitry 40. In other words, the counter causes the debug interface to become disabled by outputting the output signal to the resetting circuitry.

In some embodiments, the debug-enabling circuitry is configured not to restart the counter prior to the predetermined duration, even in response to receiving another debug-enabling input. Alternatively, the counter may be configured not to restart prior to the predetermined duration, even in response to receiving a restart instruction (e.g., from the debug-enabling circuitry). The debug interface may thus always be enabled for the same, predetermined duration.

In other embodiments, in response to receiving another debug-enabling input prior to the predetermined duration, the debug-enabling circuitry restarts the counter. The debug interface may thus be enabled for varying amounts of time.

In general, IC 20 may include any suitable components in addition to those delineated above. The various components of IC 20 may communicate with each other via a bus 24, and/or via any other suitable wires or traces.

For example, as shown in FIG. 1, IC 20 may comprise a CPU 22 and one or more memory components. Such memory components may include, for example, a read-only memory (ROM) 26, a random access memory (RAM) 28, and/or one or more registers 44. Code, such as firmware code, may be copied into RAM 28 for execution by CPU 22. The code may be copied, for example, from a non-volatile memory (NVM) 30 (comprising, for example, a flash memory or a one-time programmable (OTP) memory), or from an external memory device, such as a flash memory chip. Alternatively or additionally, the CPU may run code directly from ROM 26, NVM 30, or an external memory device.

In such embodiments, debugging input 46 may change some of the values stored in registers 44, and/or change the code loaded in RAM 28, such that the set of functions performed by CPU 22 is changed. Subsequently, the resetting circuitry may restore the values in registers 44, and/or clear RAM 28 of any code that was loaded while the debug mode was enabled.

Reference is now additionally made to FIG. 2, which is a state diagram 54 for IC 20, in accordance with some embodiments of the present invention. State diagram 54 depicts various states (or “modes”) in which IC 20 may operate, along with permissible transitions between the states.

Subsequently to being powered on, IC 20 enters a transient power-on reset (PoR) state 56. In this state, the voltage supplied to the IC increases toward an operational voltage-value. While the voltage increases, the resetting circuitry resets the IC.

Upon the voltage reaching the operational voltage-value, the IC transitions either to an open state 58 or to a locked state 60. In open state 58, debug interface 36 may be enabled without using debug-enabling circuitry 38, such that changes may be easily made to IC 20—typically, to any component of the IC—by entering suitable input via the debug interface. (Typically, there is no predetermined limit to the amount of time for which the IC may remain in open state 58.) On the other hand, in locked state 60, debug interface 36 remains disabled.

Typically, the status of a particular bit, referred to herein as a “flag,” determines whether the IC transitions to open state 58 or to locked state 60. In particular, when the flag is unset, the IC transitions to open state 58; otherwise, the IC transitions to locked state 60. The flag is typically stored in non-volatile memory 30.

Typically, during the manufacture of the IC or of a system that includes the IC, the flag is unset, such that the IC remains in the open state. Following the manufacturing process, the flag is set, such that the IC transitions to the locked state. Typically, the IC is configured not to allow any subsequent changes to the flag, such that the IC cannot return to the open state.

Alternatively—such as in cases where the IC lacks a non-volatile memory—the IC may be configured not to operate in open state 58 following the manufacture of the IC, even without setting a flag.

If, while in the locked state, a debug-enabling input is received, the IC transitions to a temporarily unlocked state 62, referred to hereinabove as a “time-limited debug mode.” During this transition, the debug interface is enabled and the counter is started, as described above. Upon the counter reaching its terminal count (TC), the counter outputs output signal 50, which causes the IC to transition to PoR state 56.

Similarly to open state 58, temporarily unlocked state 62 allows changes to the IC. However, the duration for which the IC remains in the temporarily unlocked state is limited by the counter, as described above. Moreover, typically, the temporarily unlocked state differs from the open state with respect to the types of changes that may be effected by the debugging input. In particular, although the temporarily unlocked state may allow changes to resettable components of IC 20, such as RAM 28 or another volatile memory, the temporarily unlocked state does not allow any modifications to non-resettable components of the IC, such as non-volatile memory 30.

In some embodiments, in temporarily unlocked state 62, changes to the non-resettable components of IC 20 are inhibited by counter 42. For example, as shown in FIG. 1, counter 42 may output an enable/disable signal 64 to each non-resettable component. While the counter is not counting, enable/disable signal 64 has a first value that enables the non-resettable component, such that changes may be made to the component. In response to being started, however, the counter toggles enable/disable signal 64, such that the non-resettable component is disabled. Subsequently, upon the counter reaching its terminal count, the counter again toggles the enable/disable signal, thus re-enabling the non-resettable component.

In other embodiments, changes to the non-resettable components of IC 20 are inhibited by debug-enabling circuitry 38. For example, debug-enabling circuitry 38 may output enable/disable signal 64 to each non-resettable component of the IC. In response to debug-enabling input 48, the debug-enabling circuitry may toggle the enable/disable signal so as to disable the component. Subsequently, in response to receiving output signal 50, the debug-enabling circuitry may again toggle the enable/disable signal so as to re-enable the component.

In alternate embodiments, IC 20 does not comprise a counter, such that the IC may remain in debug mode for an unlimited period of time. However, debug-enabling circuitry 38 may inhibit changes to any non-resettable components of IC 20, as described above.

It is emphasized that the particular configuration of IC 20 shown in FIG. 1 is provided by way of example only. In general, IC 20 may comprise any suitable components, which may be interconnected in any suitable arrangement, and which may perform any suitable functions. Furthermore, although the present description relates mainly to an integrated circuit, it is noted that the embodiments described herein may be applied to any suitable digital circuit.

In general, each element of circuitry described herein may include any suitable arrangement of interconnected components, configured to perform the functionality described herein. These components may include, for example, resistors, transistors, capacitors, inductors, and/or diodes, which may be interconnected using any suitable wires and/or traces.

It will be appreciated by persons skilled in the art that the present invention is not limited to what has been particularly shown and described hereinabove. Rather, the scope of embodiments of the present invention includes both combinations and subcombinations of the various features described hereinabove, as well as variations and modifications thereof that are not in the prior art, which would occur to persons skilled in the art upon reading the foregoing description. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. Apparatus, comprising:
a debug interface;
a counter, configured to output an output signal that causes the debug interface to become disabled, following a predetermined duration from a time at which the counter was started; and
debug-enabling circuitry, configured to:
receive a debug-enabling input, and
responsively to the debug-enabling input:
enable the debug interface, and
start the counter.

2. The apparatus according to claim 1, wherein the counter is configured to output the output signal to the debug interface.

3. The apparatus according to claim 1, wherein the counter is configured to output the output signal to the debug-enabling circuitry, and wherein the debug-enabling circuitry is configured to disable the debug interface in response to the output signal.

4. The apparatus according to claim 1, further comprising resetting circuitry, wherein the counter is configured to output the output signal to the resetting circuitry, and wherein the resetting circuitry is configured to revert, in response to the output signal, any changes made via the debug interface while the debug interface was enabled.

5. The apparatus according to claim 4, wherein the resetting circuitry comprises power-on reset (PoR) circuitry configured to interpret the output signal as an indication of a power-on event.

6. The apparatus according to claim 4, further comprising:
one or more resettable components; and
one or more non-resettable components,
wherein an element selected from the group of elements consisting of: the counter, and the debug-enabling circuitry is configured to inhibit the non-resettable components from being changed via the debug interface while the debug interface is enabled, and
wherein the resetting circuitry is configured to revert the changes by resetting the resettable components.

7. The apparatus according to claim 6, wherein the resettable components include a volatile memory, and wherein the non-resettable components include a non-volatile memory.

8. The apparatus according to claim 1, wherein the debug-enabling circuitry is further configured to:
receive another debug-enabling input, prior to the predetermined duration from the time at which the counter was started, and
responsively to the other debug-enabling input, restart the counter.

9. The apparatus according to claim 1, wherein the debug-enabling circuitry is configured not to restart the counter prior to the predetermined duration from the time at which the counter was started, even in response to receiving another debug-enabling input.

10. The apparatus according to claim 1, wherein the counter is further configured not to restart prior to the predetermined duration, even in response to receiving a restart instruction.

11. A method, comprising:
receiving, by debug-enabling circuitry belonging to a digital circuit, a debug-enabling input;
using the debug-enabling circuitry, responsively to the debug-enabling input:
enabling a debug interface belonging to the digital circuit, and
starting a counter; and
following a predetermined duration from a time at which the counter was started, causing the debug interface to become disabled by outputting an output signal from the counter.

12. The method according to claim 11, wherein outputting the output signal comprises outputting the output signal to the debug interface.

13. The method according to claim 11, wherein outputting the output signal comprises outputting the output signal to the debug-enabling circuitry such that the debug-enabling circuitry disables the debug interface in response to the output signal.

14. The method according to claim 11, further comprising, using resetting circuitry, in response to the output signal, reverting any changes made to the digital circuit via the debug interface while the debug interface was enabled, by resetting the digital circuit.

15. The method according to claim 14, wherein the resetting circuitry includes power-on reset (PoR) circuitry, and wherein resetting the digital circuit comprises, using the PoR circuitry:
interpreting the output signal as an indication of a power-on event; and
responsively to interpreting the output signal as an indication of a power-on event, resetting the digital circuit.

16. The method according to claim 14, wherein causing the debug interface to become disabled comprises causing the debug interface to become disabled by outputting the output signal to the resetting circuitry.

17. The method according to claim 14, wherein the digital circuit includes one or more resettable components and one or more non-resettable components, and wherein the method further includes inhibiting the non-resettable components from being changed via the debug interface while the debug interface is enabled.

18. The method according to claim 17, wherein the resettable components include a volatile memory, and wherein the non-resettable components include a non-volatile memory.

19. The method according to claim 11,
wherein starting the counter comprises starting the counter at a first time, and
wherein the method further comprises, subsequently to causing the debug interface to become disabled:
starting the counter at a second time;
prior to the predetermined duration from the second time, receiving another debug-enabling input; and
responsively to the other debug-enabling input,
restarting the counter.

20. The method according to claim 11, further comprising receiving another debug-enabling input prior to the predetermined duration, wherein outputting the output signal following the predetermined duration comprises outputting the output signal following the predetermined duration despite having received the other debug-enabling input.
